(19) United States
(12) Patent Application Publication
(10) Pub. No.: US 2026/0287675 A1
(43) Pub. Date: Sep. 24, 2026

(54) Method and Device for Determining the State of an Electric Energy Storage Device

(71) Applicant: Bayerische Motoren Werke Aktiengesellschaft, Muenchen (DE)

(72) Inventors: Simon ERHARD, Geltendorf (DE); Tobias HOFMANN, Muenchen (DE); Sebastian LUDWIG, Muenchen (DE); Andreas MAERKL, Muenchen (DE)

(21) Appl. No.: 19/474,228

(22) PCT Filed: May 6, 2024
(86) PCT No.: PCT/EP2024/062381

§ 371 Date: Oct. 10, 2025

(30) Foreign Application Priority Data
May 30, 2023 (DE) 10 2023 114 056.6

(51) Int. Cl. G01R 31/396; B60L 58/12; G01R 31/3842; G01R 31/389; H01M 10/42; H02J 7/50; H02J 7/52

(52) U.S. Cl. CPC G01R 31/396; B60L 58/12; G01R 31/3842; G01R 31/389; H01M 10/4285; H02J 7/52; H02J 7/575; B60L 2240/549; H01M 2220/20

(57) ABSTRACT

A device for determining state information regarding the state of an electric energy storage device, the energy storage device comprising a first sub-storage unit and a second sub-storage unit which can be arranged in a parallel circuit by a switching unit, wherein the device is designed to cause the first sub-storage unit to have a first sub-voltage and the second sub-storage unit to have a second sub-voltage, the two sub-voltages differing from each other. The device is also designed to determine balancing information regarding a balancing process between the first sub-storage unit and the second sub-storage unit when the first sub-storage unit and the second sub-storage unit are interconnected in a parallel circuit, and to determine the state information regarding the state of the energy storage device on the basis of the balancing information.

### BACKGROUND AND SUMMARY

The present disclosure relates to a method and to a corresponding device for determining the state of an electrical energy storage device of an on-board electrical system.

An electrically powered vehicle comprises an on-board electrical system having one or more electrical energy storge devices for supplying energy to an electric drive machine of the vehicle. The on-board electrical system, in particular, can comprise an electrical energy storage device having two or more electrical substores which, if required, can be mutually connected in series or in parallel, e.g. in order to enable the charging of the energy storage device in a flexible manner, using different charging voltages.

Individual storage cells of the electrical energy storage device, during the operation of the on-board electrical system, can undergo ageing, as a result of which e.g. the storage capacity and/or performance capability of the energy storage device is impaired. The present document addresses the technical object of determining the state-(of-health) of an electrical energy storage device having multiple substores in an efficient and accurate manner. This object is fulfilled by the present disclosure. Advantageous embodiments are also described, inter alia, in the present disclosure.

It is hereby observed that additional features of a patent claim which is dependent upon an independent patent claim, in the absence of the features of the independent patent claim or in combination with only a subset of the features of the independent patent claim, can form a standalone invention which is independent of the combination of all the features of the independent patent claim, which invention can be the subject matter of an independent claim, of a divisional application or a subsequent application. The same applies, in an equivalent manner, to the technical instruction described in the description, which instruction can form an invention which is independent of the features of the independent patent claims.

According to one aspect, a device is described for ascertaining state information with respect to the state of an electrical energy storage device, in particular of an electrochemical energy storage device (such as e.g. a lithium-ion based energy storage device). The energy storage device comprises a first substore and a second substore. The substores can respectively assume a rated voltage, wherein the rated voltages of the substores can be equal. The rated voltage can be 300 V or higher, in particular 400 V or higher.

The substores can respectively comprise a plurality of storage cells. In particular, the substores can respectively comprise a series-connected arrangement of cell modules, wherein the individual cell modules can respectively comprise one or more storage cells which are mutually arranged in parallel. A cell module can comprise e.g. M storage cells arranged in parallel, for example where M≥2, e.g. M=3, or M=4, or M=5. Moreover, the substores can respectively comprise N series-connected cell modules, e.g. N≥2, or N≥10, or N≥50, or N≥100.

The individual cell modules can assume a rated cell voltage (e.g. between 2V and 5V), and the rated voltage of the respective substore can correspond to N-times the rated cell voltage.

The energy storage device can further comprise a switch unit, wherein the switch unit can comprise one or more (semiconductor-based and/or mechanical) switching elements. The switch unit can be designed to configure the substores in various ways, e.g. in a series-connected arrangement, in a parallel-connected arrangement and/or in a mutually separated arrangement. The device can be designed to employ a variation of the arrangement of the substores of the energy storage device to the effect that state information with respect to the state of the energy storage device can be ascertained in an efficient and accurate manner.

During the variation of the arrangement of substores, balancing information and/or relaxation information can be acquired (as described hereinafter), and state information ascertained on the basis of balancing information and/or relaxation information. Balancing information and/or relaxation information can be acquired by reference to one or more (internal) measuring units of the energy storage device. The one or more measuring units can be configured to acquire the current flowing through the respective substore and/or through the individual cell modules, and/or the voltage on the respective substore and/or on the individual cell modules.

The device is designed to bring about the assumption of a first partial voltage by the first substore, and of a second partial voltage by the second substore, which partial voltages are mutually different. A relatively small deviation of the partial voltages can be achieved (e.g. a deviation of 5% or less, or 2% or less, or 1% or less; and/or a deviation of 0.1% or more, or of 0.5% or more).

The deviation in partial voltages can be achieved in an efficient manner during the operation of the energy storage device (for example by the configuration of the substores in a series-connected arrangement).

The device is further designed to ascertain information with respect to the balancing process (of partial voltages) between the first substore and the second substore upon the interconnection of the first substore and the second substore in a parallel-connected arrangement (by reference to the one or more measuring units of the energy storage device). In particular, balancing information can be ascertained with respect to the balancing current which flows between the first substore and the second substore in response to the difference between the first partial voltage and the second partial voltage.

In particular, balancing information can comprise the following:
Current information with respect to the temporal characteristic, particularly with respect to a (temporal) variation, of the balancing current between the first substore and the second substore; and/or
Voltage information with respect to the temporal characteristic, particularly with respect to a (temporal) variation of the first partial voltage and/or of the second partial voltage; and/or
Voltage information with respect to the temporal characteristic, particularly with respect to a (temporal) variation, of the cell voltage on a cell module of the first and/or second substore.

The device is further designed to ascertain state information with respect to the state of the energy storage device (in particular of the first substore, of the second substore and/or of the individual cell modules) on the basis of balancing information. In particular, on the basis of current information and on the basis of voltage information, state information can be ascertained with respect to the state of the first substore, of the second substore and/or of an individual cell module. For example, on the basis of current information and on the basis of voltage information, resistance information with respect to the internal resistance of the first substore and/or of the second substore and/or of an individual cell module can be ascertained by way of state information. The temporal variation of the respective voltage, in relation to the corresponding temporal variation of the balancing current, can be employed for the ascertainment of resistance information. On the basis of resistance information, in an accurate manner, the performance capability and/or the state-of-health of the respective substore or of the respective cell module can be ascertained by way of state information.

A device is thus described which is configured, during the operation of the energy storage device, in an energy-efficient manner, to acquire balancing information with respect to a balancing process between the substores of the energy storage device, in order to ascertain the state (in particular the internal resistance and/or the performance capability and/or the storage capacity) of a substore and/or of a cell module of the energy storage device, in an accurate manner.

The device can be designed, during the operation of the energy storage device, to detect an operating situation wherein the first substore and the second substore (e.g. proceeding from a series-connected arrangement) are interconnected in a parallel-connected arrangement. Balancing information for the ascertainment of state information with respect to the state of the energy storage device can then be ascertained and, in particular, acquired, in a particularly efficient manner, in the context of the operating situation thus detected. A particularly efficient ascertainment of the state of the energy storage device can be executed accordingly.

The device can be designed, in the context of a charging process for charging the energy storage device, to achieve the assumption by the first substore of a first partial voltage, and the assumption by the second substore of a second partial voltage, which partial voltages are different from one another. For example, for the charging process, the substores can be configured in a series-connected arrangement (which, optionally, will automatically result in a deviation of the partial voltages). Alternatively or additionally, a selective charging of the first or the second substore can be executed (by a DC voltage converter), in order to achieve a resulting deviation of the partial voltages. Thus, in a particularly efficient manner, the precondition for the balancing process for the acquisition of balancing information can be provided.

The device can be designed, in the event of a plurality of different states-of-charge of the energy storage device, to respectively bring about the assumption by the first substore of a first partial voltage, and the assumption by the second substore of a second partial voltage, which partial voltages are different from one another and, in the event of a plurality of different states-of-charge of the energy storage device, to respectively ascertain balancing information upon the interconnection of the first substore and the second substore in a parallel-connected arrangement (e.g. proceeding, in each case, from a series-connected arrangement of the first substore and the second substore).

The plurality of states-of-charge can comprise e.g. five or more, or ten or more different states-of-charge, which states range (optionally, in an evenly-distributed arrangement) between 5% and 95%, or between 0% and 100% of the storage capacity of the energy storage device. For example, for the various states-of-charge, current information and/or voltage information can be respectively ascertained.

State information with respect to the state of the energy storage device can then be ascertained in a particularly accurate manner on the basis of balancing information for the plurality of different states-of-charge of the energy storage device. For example, for the different states-of-charge, in each case, resistance information with respect to the internal resistance (of a substore and/or of a cell module) can be ascertained. The state of the energy storage device can thus be characterized in a particularly accurate manner.

According to a further aspect, a further device for determining state information with respect to the state of an electrical energy storage device is described, wherein the energy storage device comprises a first substore and a second substore. The switch unit can be designed to configure the substores in a parallel-connected arrangement, or in a mutually separated arrangement. Features described in the present document with respect to the energy storage device and/or with respect to a device for determining state information are also applicable to this further device, either individually or in combination.

The device is designed such that the first substore and the second substore, proceeding from a parallel-connected arrangement, are separated from one another. This separation is preferably executed during the operation of the energy storage device (e.g. upon a transition from a parallel-connected arrangement to a series-connected arrangement of the substores).

The device is further designed to ascertain (and, in particular, to acquire) relaxation information with respect to a relaxation process (of the partial voltage) of the first substore and/or of the second substore, further to the separation of the first substore and the second substore. Relaxation information can be ascertained by reference to one or more (internal) measuring units of the energy storage device.

Relaxation information can comprise the following:
Voltage information with respect to the temporal characteristic of the first partial voltage of the first substore and/or of the second partial voltage of the second substore; and/or
Voltage information with respect to the temporal characteristic of the cell voltage on at least one cell module of the first and/or second substore.

The device is moreover designed to determine state information with respect to the state of the energy storage device on the basis of relaxation information. State information can be ascertained by the employment of an, in particular machine learning-based pattern recognition algorithm, on the basis of relaxation information.

State information can comprise information with respect to the reduction of the storage capacity of the energy storage device and/or information with respect to deposits on an electrode of one or more storage cells of the energy storage device, in particular information with respect to lithium plating in the energy storage device.

The device can be designed to execute a frequency analysis of balancing information and/or of relaxation information, in particular of current information and/or of voltage information, in order to ascertain state information with respect to the state of the energy storage device. For example, a transformation (e.g. of one or more temporal characteristics of current and/or of voltage) from the time domain to the frequency domain can be executed. Thereafter, resistance information can be ascertained in the frequency domain. For example, resistance information, in particular the internal resistance, can be ascertained for a plurality of different frequencies. By the employment of a frequency analysis, the state of the energy storage device can be ascertained in a particularly accurate manner.

According to a further aspect, an on-board electrical system (for a vehicle) is described, which system comprises at least one of the devices described in the present document.

According to a further aspect, a (road) motor vehicle is described (in particular a passenger vehicle, or a heavy goods vehicle, or a bus, or a motor cycle) is described, which vehicle comprises at least one of the devices described in the present document and/or comprises the on-board electrical system described in the present document.

According to a further aspect, a method is described for determining state information with respect to the state of an electrical energy storage device, wherein the energy storage device comprises a first substore and a second substore, which substores, by a switch unit (having one or more switching elements) can be configured in a parallel-connected arrangement (e.g. proceeding from a series-connected arrangement).

The method comprises the achievement of a first partial voltage by the first substore, and of a second partial voltage by the second substore, which partial voltages are mutually different (e.g. are mutually different by 0.1% or more, by 0.5% or more, or by 1% or more). This can be achieved e.g. by the configuration of the first and second substores in a series-connected arrangement.

The method further comprises the ascertainment of balancing information with respect to the balancing operation between the first substore and the second substore (for the equalization of partial voltages on the substores) upon the interconnection of the first substore and the second substore in a parallel-connected arrangement (optionally proceeding from a series-connected arrangement of the substores). The method further comprises the ascertainment of state information with respect to the state of the energy storage device, on the basis of balancing information.

According to a further aspect, a method is described for determining state information with respect to the state of an electrical energy storage device, wherein the energy storage device comprises a first substore and a second substore, which substores, by a switch unit, can be configured in a parallel-connected arrangement, or can be mutually separated.

The method comprises the achievement of a mutual separation of the first substore and the second substore, proceeding from a parallel-connected arrangement (such that no current can flow between the substores and/or from or into the individual substores). The method moreover comprises the ascertainment of relaxation information with respect to the relaxation process (of the partial voltage) of the first substore and/or of the second substore, further to the separation of the first substore and the second substore. The method further comprises the ascertainment of state information with respect to the state of the energy storage device, on the basis of relaxation information.

According to a further aspect, a software (SW) program is described. The SW program can be designed to be executed on a processor (e.g. on a controller of a vehicle), for the consequent execution of at least one of the methods described in the present document.

According to a further aspect, a storage medium is described. The storage medium can comprise a SW program, which program is designed to be executed on a processor, for the consequent execution of at least one of the methods described in the present document.

It should be observed that the methods, devices and systems described in the present document can be employed both individually and in combination with other methods, devices and systems described in the present document. Moreover, any aspects of the methods, devices and systems described in the present document can be mutually combined in a variety of ways. In particular, features of the claims can be mutually combined in a variety of ways. Moreover, features enclosed in brackets are to be understood as optional features.

The present disclosure is described in greater detail hereinafter with reference to exemplary embodiments.

### BRIEF DESCRIPTION OF DRAWINGS

FIG. 1a shows exemplary components of a vehicle having an electric drive machine;

FIG. 1b shows an exemplary on-board electrical system of a vehicle;

FIG. 1c shows an exemplary series-connected arrangement of substores of the electrical energy storage device;

FIG. 1d shows an exemplary parallel-connected arrangement of substores of the electrical energy storage device;

FIGS. 2a, 2b, 2c, and 2d show an exemplary sequence of configurations of substores associated with a transition from a series-connected arrangement to a parallel-connected arrangement of substores;

FIG. 3a shows an exemplary temporal characteristic of the balancing current associated with the parallel connection of substores;

FIG. 3b shows an exemplary temporal characteristic of the partial voltage of a substore associated with the separation of substores; and

FIGS. 4a and 4b respectively show a flow diagram of an exemplary method for determining state information with respect to the state of an electrical energy storage device.

### DETAILED DESCRIPTION OF DRAWINGS

As described above, the present document addresses the determination of the state of an electrical energy storage device, which device e.g. is an element of the on-board electrical system of a vehicle. In this connection, Fig. la shows an exemplary vehicle 100 having at least one electrical energy storage device 105 for storing electrical energy for the operation of an electric drive machine 103 of the vehicle 100. The energy storage device 105 can assume a rated voltage of 300 V or higher, in particular of 800 V or higher. A (control) device 101 of the vehicle 100 can be designed for controlling the operation of the electric drive machine 103 by electrical energy from the energy storage device 105.

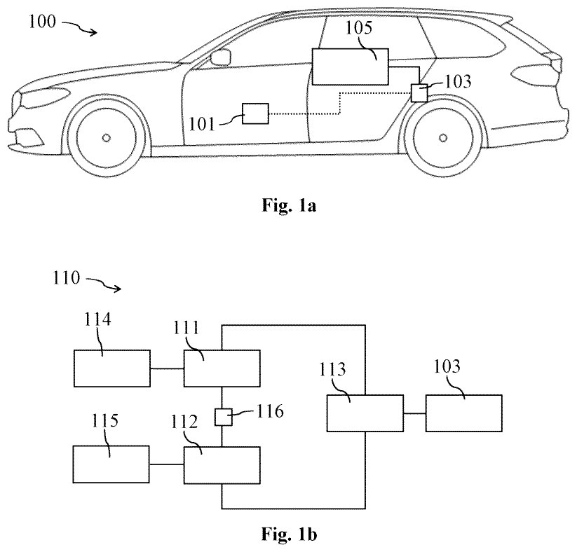

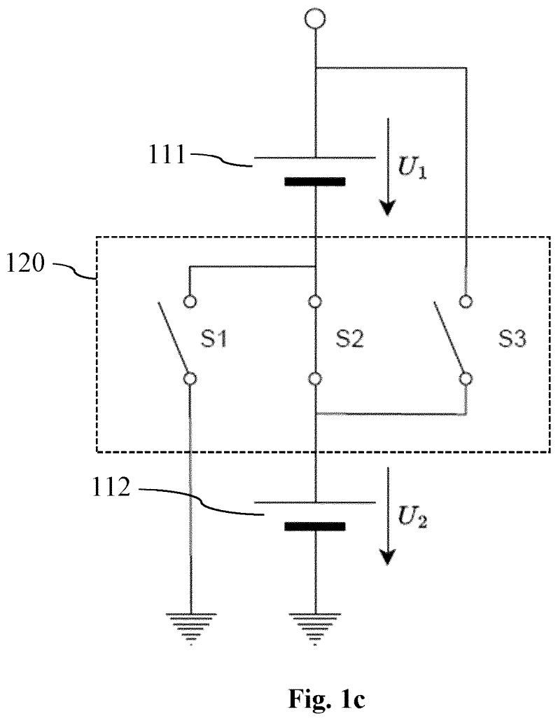

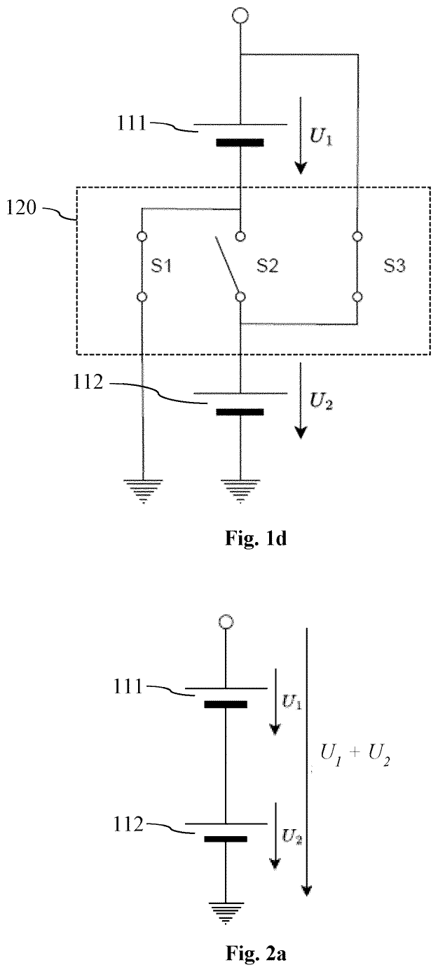

FIG. 1b shows an exemplary on-board electrical system 110 for a vehicle 100. The on-board electrical system 110 can comprise an inverter 113 which is designed, on the basis of the DC voltage which is supplied by the energy storage device 105, to generate AC voltages for one or more phases of the electric drive machine 103.

The energy storage device 105 of the vehicle 100 can comprise multiple substores 111, 112 which, if required, can be connected in series in order to raise the effective rated voltage of the energy storage device 105 (and thus the available electrical capacity for the drive machine 103). The on-board electrical system 110 represented in FIG. 1b comprises a first (sub-)store 111 and a second (sub-)store 112, each of which can assume e.g. a partial rated voltage such that, by the series connection of the two stores 111, 112, an effective rated voltage is produced which is double the partial rated voltages of the individual substores 111, 112.

The series or serial connection of the two substores 111, 112 can be executed or suppressed by a serial switching element 116 (e.g. by a semiconductor-based switching element or by a (mechanical) relay). By the closing of the serial switching element 116, it can be achieved that the effective rated voltage delivered by the series-connected arrangement of the substores 111, 112 is applied to the inverter 113, and is available for the operation of the drive machine 103.

The on-board electrical system 110 represented in FIG. 1b further comprises a first DC voltage converter 114 which is, or which can be coupled to the first substore 111, and which is designed to extract electrical energy from the first substore 111 or to inject electrical energy into the first substore 111 (for a charging process). The on-board electrical system 110 can further comprise a corresponding second DC voltage converter 115 which is, or which can be coupled to the second substore 112, and which is designed to extract electrical energy from the second substore 112 or to inject electrical energy into the second substore 112 (for a charging process).

The on-board electrical system 110, as exemplarily represented in FIGS. 1c and 1d, can comprise a switch unit 120 which enables the substores 111, 112 to be configured in series (as represented in FIG. 1c) or to be mutually configured in parallel (as represented in FIG. 1d), or to be mutually separated (as represented in FIG. 1b). The switch unit 120 can comprise a first switching element S1 which is configured to couple the second pole of the first substore 111 to the second pole of the second substore 112 and/or to a reference point (e.g. to ground and/or to the negative pole of the inverter 113), or to execute the decoupling thereof. The switch unit 120 can comprise a second switching element S2 which is configured to couple the second pole of the first substore 111 to the first pole of the second substore 112, or to execute the decoupling thereof. The switch unit 120 can comprise a third switching element S3 which is configured to couple the first pole of the second substore 112 to the first pole of the first substore 111 and/or to a working point (e.g. to the positive pole of the inverter 113), or to execute the decoupling thereof.

The first substore 111 can assume a first partial voltage U1, and the second substore 112 can assume a second partial voltage U2. If the two substores 111, 112 are connected in series (see FIG. 1c), the resulting overall voltage (i.e. the on-board electrical system voltage) between the working point and the reference point is the sum of the two partial voltages U1+U2. If the two substores 111, 112 are mutually connected in parallel (see FIG. 1d), the overall voltage between the working point and the reference point corresponds to the partial voltages U1=U2.

During the service life of the energy storage device 105, it can be necessary and/or advantageous to ascertain the state of the energy storage device 105, particularly with respect to the available storage capacity of the energy storage device 105. To this end, an external measuring device can be employed, which measuring device is configured to acquire measured values with respect to the energy storage device 105, and to ascertain state information with respect to the state of the energy storage 105 on the basis thereof. The employment of an external measuring device is associated with an additional effort and, typically, is only possible in the context of the servicing of the vehicle 100. Moreover, the acquisition of measured values can require the extraction of an electrical charge from the energy storage device 105, which extraction is associated with an energy loss.

In the present document, measures are described which enable state information with respect to the state of the energy storage device 105 to be ascertained during the operation of the on-board electrical system 110 and/or with no associated energy loss and/or without the employment of an external measuring device.

During the operation of the energy storage device 105, it can be necessary for the substores 111, 112 (e.g. proceeding from a series-connected arrangement) to be mutually connected in parallel, e.g. in order to enable a charging process with a reduced charging voltage. According to a further example, it can be necessary for the two substores 111, 112 (e.g. proceeding from a parallel-connected arrangement) to be mutually separated (e.g. in order to enable the subsequent connection of the substores 111, 112 in series). The switching process to a parallel-connected arrangement and/or the switching process for the separation of the substores 111, 112 can be employed for ascertaining state information with respect to the state of the energy storage device 105.

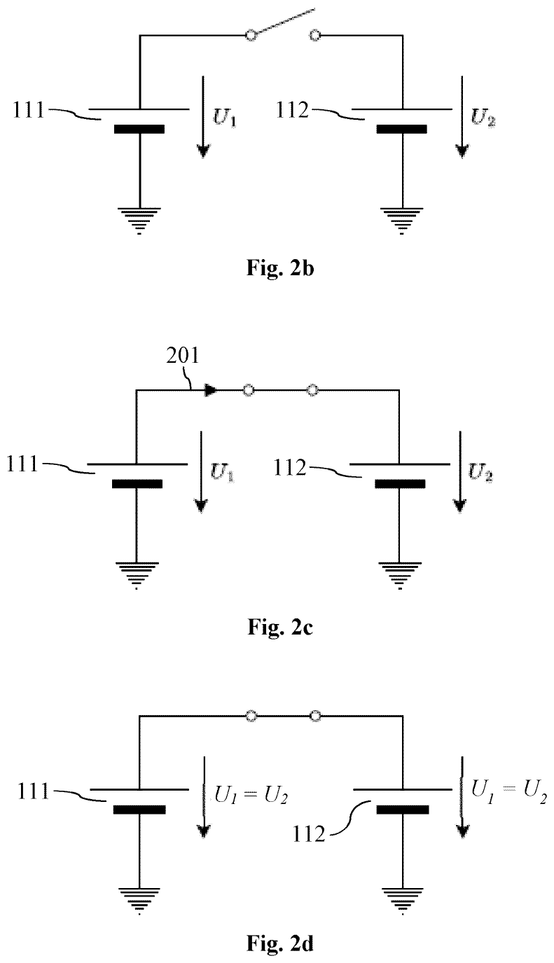

In FIGS. 2a to 2d, an exemplary transition is represented from a series-connected arrangement of the substores 111, 112 (FIG. 2a) to a parallel-connected arrangement of the substores 111, 112 (FIG. 2c and FIG. 2d). The substores 111, 112 can firstly be mutually separated (FIG. 2b), which separation can be achieved e.g. by opening the switching elements S1, S2 and S3. Thereafter, the substores 111, 112 can be mutually configured in parallel (FIG. 2c), which configuration can be achieved e.g. by closing the switching elements S1 and S2.

On the grounds that the first partial voltage U1 and the second partial voltage U2, in the event of a series-connected arrangement of the substores 111, 112, are typically different, and thus assume a delta Δ=U1−U2, with effect from the time of parallel connection of the substores 111, 112, a balancing current 201 flows (e.g. from the first substore 111 to the second substore 112, if delta Δ>0; or from the second substore 112 to the first substore 111, if delta Δ<0). The balancing current 201 flows for such time until the two partial voltages of the two substores 111, 112 have equalized (such that delta Δ=0).

The balancing current 201 can be acquired by an internal measuring unit of the energy storage device 105. Moreover, the first partial voltage and the second partial voltage and/or the voltage delta can also be acquired by one or more internal measuring units of the energy storage device 105. Optionally, the cell voltages of the individual cell modules of the substores 111, 112 can be acquired by one or more internal measuring units of the energy storage device 105.

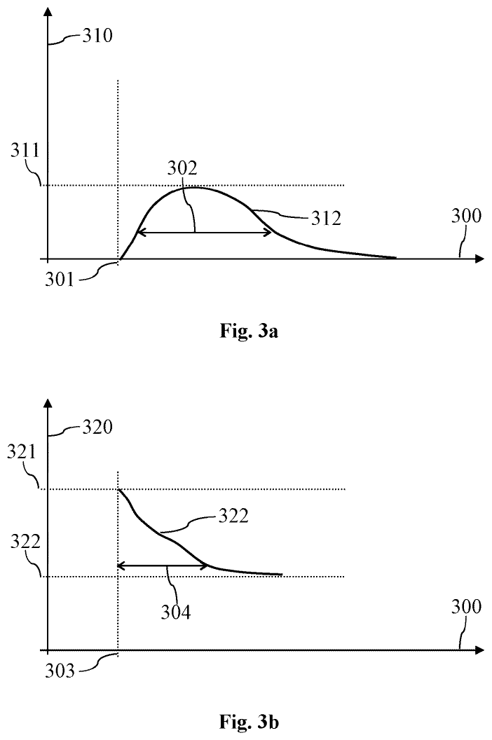

FIG. 3 shows an exemplary temporal characteristic 312 of the balancing current 201, i.e. the current intensity 310 of the balancing current 201 as a function of time 300. The balancing current 201 flows with effect from the switching time point 301 at which the parallel connection of the substores 111, 112 is executed. The temporal characteristic 312 of the balancing current 201 can be analyzed in order to ascertain state information with respect to the state of the energy storage device 105. In particular, state information can be ascertained on the basis of one or more properties of the temporal characteristic 312 of the balancing current 201. Exemplary properties are as follows: the maximum current intensity 311, the temporal gradient of the characteristic 312 of the balancing current 201 and/or the temporal duration 302 of the balancing current pulse.

For example, at a specific time point during the balancing current pulse, the variation of the current intensity 310 of the balancing current 201 (i.e. ΔI) and the variation of the first or second partial voltage U1, U2 (i.e. ΔU with respect to U1 or U2). The internal resistance R of the first or second substores 111, 112 can be ascertained from the ratio R=ΔU/ΔI. From the internal resistance R, the storage capacity of the first or second substore 111, 112 can be inferred.

In a corresponding manner, state information with respect to the state of individual cell modules of the first and/or second substore 111, 112 can be ascertained. To this end, the variation of the cell voltage (i.e. ΔU) which occurs in a cell module in response to the variation of the current intensity 310 of the balancing current 201 (i.e. ΔI) can be acquired, in order to ascertain the internal resistance of this cell module.

As described above, an energy storage device 105 can assume a changeover matrix configuration or a switchable center tap. During the charging process, which employs a 400 V infrastructure, the storage device 105, by the parallel connection of the two half-stores 111, 112, can execute a transition from a 800 V configuration to a 400 V configuration. Intrinsic parameter fluctuations in the two half-stores 111, 112 typically generate an asymmetry in the voltages of the two half-stores 111, 112. By the interconnection of the two half-stores 111, 112, a balancing current pulse is generated, which pulse can be employed for the characterization of logic cells (i.e. parallel assemblies or cell modules) of the two half-stores 111, 112. Alternatively or additionally to this intrinsic asymmetry, by the DC/DC converter 114, 115, an asymmetry can also be deliberately imposed upon the partial voltages of the half-stores 111, 112. For a relatively short time (e.g. a few seconds and/or minutes) only one half-store 111, 112 can thus be charged, and the balancing process can be employed thereafter for the characterization of the energy storage device 105.

For example, on a wallbox, only 11 kW of charging capacity is available, and the energy storage device 105 can be charged, e.g. by AC charging in a diagnostic mode. This can be applied as a trigger for the employment of the balancing current pulse for the characterization of the storage device. In preparation for the charging process, the storage device 105 executes a changeover from a 800 V to a 400 V architecture. As a result of the asymmetrical charging of the two half-stores 111, 112, a balancing current pulse is generated (which pulse typically assumes a relatively low electrical capacity). The balancing process enables a characterization of the energy storage device 105. During the charging process, by a deliberate asymmetrical charging and a subsequent balancing current pulse, the internal resistance can be ascertained (e.g. for different states-of-charge of the energy storage device 105).

By the measures described in the present document, the internal resistance of the energy storage device 105 and/or of the individual parallel assemblies or cell modules of the energy storage device 105 can be ascertained. The duration 302 of the balancing current pulse can be controlled by power electronics in an accurate manner. By an asymmetrical charging of the energy storage device 105, in an (AC) charging process, a SOC-dependent characterization process for the entire SOC range can be executed, with no resulting loss of electrical charge (i.e. with no loss of energy). No external measuring device is required, as the storage device 105 typically already assumes the requisite measuring technology and capacity. Characterization of the energy storage device 105 can be executed directly in a vehicle 100, with no necessity for a workshop visit, as a result of which both time and costs can be economized. Moreover, frequency (ratios) of the charging and/or balancing process can be employed as an indicator and/or by way of further information for ascertaining the state of the energy storage device 105.

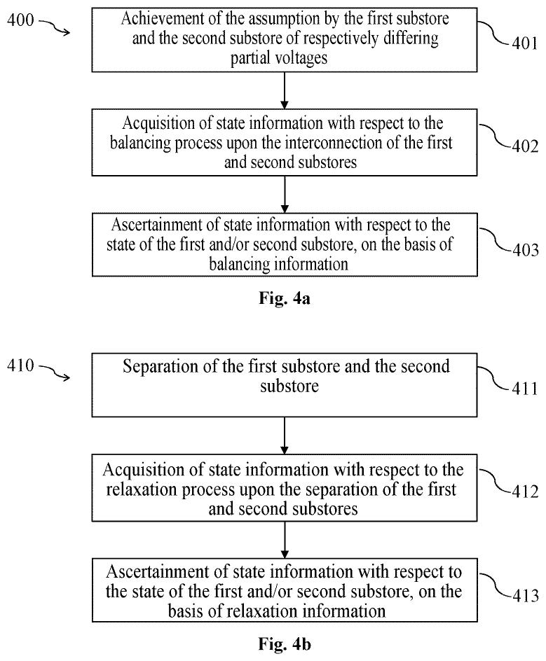

FIG. 4a shows a flow diagram of an exemplary (and optionally computer-implemented) method 400 for determining state information with respect to the state of an electrical energy storage device 105, in particular of an electrochemical energy storage device, for example a lithium-ion based energy storage device. The energy storage device 105 comprises a first substore 111 and a second substore 112 which, by a switch unit 120 (having one or more switching elements S1, S2, S3), can be configured in a series-connected arrangement or in a parallel-connected arrangement. The substores 111, 112 can respectively comprise a plurality of storage cells, wherein the storage cells can be grouped in cell modules, each having one or more storage cells arranged in parallel. The substores 111, 112 can respectively comprise a series-connected arrangement of cell modules. The substores 111, 112 can assume the same rated voltage (e.g. 300 V or higher, in particular 400 V).

The method 400 comprises the achievement 401 by the first substore 111 of a first partial voltage, and by the second substore 112 of a second partial voltage, which partial voltages are mutually different. This can be achieved, for example, wherein the substores 111, 112 are configured in a series-connected arrangement (e.g. during a charging process of the energy storage device 105). On the grounds of intrinsic fluctuations (even in the event of an equal rated voltage of the substores 111, 112), different partial voltages can occur. Partial voltages can assume a mutual deviation, e.g. of between 0.1% and 2%.

The method 400 further comprises the determination 402 of balancing information with respect to the balancing process between the first substore 111 and the second substore 112 upon the interconnection of the first substore 111 and the second substore 112 in a parallel-connected arrangement. Parallel connection of the substores 111, 112, on the grounds of the (relatively small) voltage differential, generates a balancing current 201 between the substores 111, 112. Balancing information can comprise information with respect to the balancing current 201 and/or with respect to the balancing process of the partial voltages of the substores 111, 112.

Interconnection of the substores 111, 112 in a parallel-connected arrangement can preferably be executed during the operation of the electrical energy storage device 105, e.g. in preparation for a charging process with a relatively low charging voltage (corresponding to the rated voltages of the substores 111, 112). Balancing information can thus be ascertained in an efficient manner (and, in particular, can be executed without energy losses).

The method 400 further comprises the determination 403 of state information with respect to the state of the energy storage device 105 on the basis of balancing information. On the basis of balancing information, the internal resistance of the first substore 111, of the second substore 112 and/or of one or more individual cell modules of the energy storage device 105 can be ascertained. On the basis of the internal resistance, the state-of-health (SOH), in particular the SOHr (state-of-health resistance) and/or the performance capability of the respective storage unit (the substores 111, 112, or a cell module) can be inferred by way of state information. On the basis of internal resistance, moreover, the storage capacity (in particular the SOHc, or capacitance) of the respective storage unit (the substores 111, 112, or a cell module) can be inferred by way of state information.

Alternatively or additionally to a balancing process associated with the parallel connection of the substores 111, 112, a relaxation process associated with the separation of the substores 111, 112 can be employed for the determination of state information with respect to the state of the energy storage device 105. In a parallel-connected arrangement, the substores 111, 112 typically assume equal partial voltages U1=U2. If the two substores 111, 112 are mutually decoupled (e.g. by opening the switching elements S1, S2, S3), on the grounds of a relaxation process, a variation of the individual partial voltages of the substores 111, 112 (in the absence of a current flux) can occur.

A relaxation process of storage unit (e.g. of a substore 111, 112 or of a cell module) occurs e.g. further to a situation (e.g. a charging process or a grid connection) in which storage voltage of the storage device is maintained at a specific voltage level. Further to the interruption of the respective voltage, a relaxation process can occur, wherein the storage voltage of the storage device approaches the open-circuit voltage of the storage device, i.e. a decay of overvoltages occurs. In the event of an exclusively parallel connection of the substores 111, 112, in the absence of a current flux, after a sufficient time interval, the two open-circuit voltages of the half-stores assume an equal value (even in conjunction with different states-of-charge of the half-stores 111, 112). Further to the interruption of parallel connection, a relaxation process (in the two substores 111, 112) can then occur (wherein the partial voltages approach the corresponding open-circuit voltages of the two substores 111, 112).

FIG. 3b shows an exemplary temporal characteristic 322 of the partial voltage of a substore 111, 112 (i.e. the voltage value 320 as a function of time 300), proceeding from the time point 303 at which the two substores 111, 112 are decoupled. The partial voltage can also vary e.g. from a starting value 321 to a final value 322. The temporal characteristic 322 of the partial voltage, in particular one or more properties of the temporal characteristic 322 (such as e.g. the delta between the final value 322 and the starting value 321, the temporal duration 304 of the variation of the partial voltage, etc.) can be employed for the determination of state information with respect to the state of the energy storage device 105.

An energy-neutral self-diagnosis of the two half-stores 111, 112 can be achieved further to a charging process at 800 V. In a fully-charged state, the storage device 105 can be switched to 2×400 V (i.e. a parallel-connected arrangement), in order to execute a self-excitation. Thereafter, the one or more switch units S1, S2, S3 can be re-opened, in order to acquire the relaxation behavior of the half-stores 111, 112. This behavior of the respective half-stores 111, 112 can be employed for the determination of a storage asymmetry and/or of the resistance of the individual half-stores 111, 112, and/or for the detection of potential lithium plating within the respective half-stores 111, 112. This enables, inter alia, a conclusion with respect to a potential inconsistency of the cell module strings of the respective half-stores 111, 112. A method for the detection of lithium plating is described in S. Schindler et al., “Voltage relaxation and impedance spectroscopy as in-operando methods for the detection of lithium plating on graphitic anodes in commercial lithium-ion cells”, Journal of Power Sources 304 (February 2016), 170-180. The content of this document is included, in its entirety, by way of reference thereto in the present document.

FIG. 4b shows a flow diagram of an exemplary (and, optionally, computer-implemented) method 410 for determining state information with respect to the state of an electrical energy storage device 105. It should be observed that individual features of the two methods 400, 410 can be mutually combined in an arbitrary manner.

As described above, the energy storage device 105 comprises a first substore 111 and a second substore 112 which, by a switch unit 120 (having one or more switching elements S1, S2, S3), can be configured in a parallel-connected arrangement, or can be mutually separated (such that no current can flow between the two substores 111, 112). The method 410 can be executed during the operation of the energy storage device 105.

The method 410 comprises an achievement 411 by the first substore 111 and the second substore 112, proceeding from a parallel-connected arrangement, of a mutually separated state. This can be executed e.g. further to a charging process of the substores 111, 112, wherein the charging process is executed at a relatively low charging voltage (in the region of the rated voltages of the substores 111, 112). This separation can be executed e.g. as an intermediate step in the switchover of the substores 111, 112 from a parallel-connected arrangement to a series-connected arrangement.

The method 410 further comprises the determination 412 of relaxation information with respect to the (voltage) relaxation process of the first substore 111 and/or of the second substore 112 further to the separation of the first substore 111 and the second substore 112. If the substores 111, 112 are configured in a parallel-connected arrangement, the substores 111, 112 typically assume equal partial voltages. Further to the separation of the substores 111, 112, as a result of the relaxation process, a variation of the partial voltage of the first and/or of the second substore 111, 112 can occur (with no resulting current flux). Relaxation information can indicate the temporal characteristic of the first and/or second substore 111, 112, and/or the temporal characteristic of the cell voltage of a cell module.

The method 410 further comprises the determination 413 of state information with respect to the state of the energy storage device 105, on the basis of relaxation information. To this end, a pattern recognition algorithm can be employed, which algorithm is configured, on the basis of relaxation information (in particular on the basis of a temporal characteristic of a partial voltage of a substore 111, 112 and/or of a cell voltage of a cell module), to detect a pattern for a specific state (e.g. for a specific state of degradation, for example lithium plating) of the respective substore 111, 112 and/or of the respective cell module.

By the measures described in the present document, the SOHr, performance capability and/or the SOHc of a substore 111, 112 and/or of a cell module of an energy storage device 105 can be ascertained in an efficient and accurate manner. Optionally, from a detected increase in the internal resistance of a substore 111, 112 and/or of a cell module, a reduction in the storage capacity of the substore 111, 112 and/or of the cell module can be inferred.

The present disclosure is not limited to the exemplary embodiments represented. In particular, it should be observed that the description and the figures are only intended by way of an exemplary illustration of the methods, devices and systems proposed.

1-15. (canceled)

16. A device for determining state information with respect to a state of an electrical energy storage device, wherein the electrical energy storage device comprises a first substore and a second substore that, using a switch unit, can be configured in a parallel-connected arrangement, wherein the device is configured to:
bring about an assumption of a first partial voltage by the first substore, and of a second partial voltage by the second substore, which partial voltages are mutually different;
determine balancing information with respect to a balancing process between the first substore and the second substore, upon interconnection of the first substore and the second substore in the parallel-connected arrangement; and
determine state information with respect to the state of the electrical energy storage device on a basis of the balancing information.

17. The device according to claim 16, wherein the device is configured to:
determine the balancing information with respect to a balancing current that flows between the first substore and the second substore in response to a difference between the first partial voltage and the second partial voltage.

18. The device according to claim 16,
wherein the balancing information comprises:
current information with respect to a temporal characteristic comprising a variation of a balancing current between the first substore and the second substore; and/or
voltage information with respect to a temporal characteristic comprising a variation of the first partial voltage and/or of the second partial voltage.

19. The device according to claim 18, wherein the device is configured to:
determine, on a basis of current information and on a basis of voltage information, resistance information with respect to an internal resistance of the first substore and/or of the second substore, by way of the state information.

20. The device according to claim 16,
wherein the first substore and/or the second substore respectively comprise a series-connected arrangement of cell modules, each comprising one or more storage cells, and
wherein the device is configured to:
determine current information with respect to a temporal characteristic comprising a variation of a balancing current between the first substore and the second substore, by way of an element of balancing information;
determine voltage information with respect to a temporal characteristic comprising a variation of a cell voltage on a cell module of the first and/or second substore, by way of the balancing information; and
determine the state information with respect to a state of the cell module, on a basis of current information and on a basis of voltage information.

21. The device according to claim 16, wherein the device is configured to:
detect, during operation of the electrical energy storage device, an operating situation wherein the first substore and the second substore are interconnected in a parallel-connected arrangement; and
ascertain balancing information for determining the state information in a context of the detected operating situation.

22. The device according to claim 16, wherein the device is configured to:
in a context of a charging process for charging the electrical energy storage device, bring about the assumption by the first substore of the first partial voltage, and by the second substore of the second partial voltage, which partial voltages are mutually different.

23. The device according to claim 16, wherein the device is configured to:
in an event of a plurality of different states-of-charge of the electrical energy storage device, respectively bring about the assumption by the first substore of the first partial voltage, and the assumption by the second substore of the second partial voltage, which partial voltages are different from one another;
in an event of a plurality of different states-of-charge of the electrical energy storage device, respectively ascertain balancing information upon the interconnection of the first substore and the second substore in the parallel-connected arrangement; and
determine the state information on a basis of the balancing information for the plurality of different states-of-charge of the electrical energy storage device.

24. The device according to claim 16, wherein the device is configured to:
bring about a transition of the first substore and the second substore from a series-connected arrangement to the parallel-connected arrangement in order to bring about the assumption by the first substore of the first partial voltage, and by the second substore of the second partial voltage, which partial voltages, upon the interconnection of the first substore and the second substore in the parallel-connected arrangement, are mutually different.

25. A device for determining state information with respect to a state of an electrical energy storage device, wherein the electrical energy storage device comprises a first substore and a second substore that, via a switch unit, can be configured in a parallel-connected arrangement, wherein the device is configured to:
bring about an assumption of a first partial voltage by the first substore, and of a second partial voltage by the second substore, which partial voltages are mutually different;
determine relaxation information with respect to a relaxation process between the first substore and/or the second substore, further to a separation of the first substore and the second substore; and
determine state information with respect to a state of the electrical energy storage device on a basis of the relaxation information.

26. The device according to claim 25,
wherein relaxation information comprises:
voltage information with respect to a temporal characteristic of a first partial voltage of the first substore and/or of a second partial voltage of the second substore; and/or
voltage information with respect to a temporal characteristic of a cell voltage on at least one cell module of the first and/or second substore.

27. The device according to claim 25,
wherein state information comprises information with respect to a reduction of a storage capacity of the electrical energy storage device, and/or information with respect to deposits on an electrode of one or more storage cells of the electrical energy storage device.

28. The device according to claim 25, wherein the device is configured to:
ascertain the state information using a machine learning-based pattern recognition algorithm on a basis of the relaxation information.

29. A method for determining state information with respect to a state of an electrical energy storage device, wherein the electrical energy storage device comprises a first substore and a second substore which, via a switch unit, can be configured in a parallel-connected arrangement, the method comprising:
achieving a first partial voltage by the first substore, and a second partial voltage by the second substore, which partial voltages are mutually different;
ascertaining balancing information with respect to a balancing operation between the first substore and the second substore upon an interconnection of the first substore and the second substore in the parallel-connected arrangement; and
ascertaining state information with respect to a state of the electrical energy storage device on a basis of the balancing information.
